(19) United States
(12) Patent Application Publication
(10) Pub. No.: US 2008/0171132 A1
(43) Pub. Date: Jul. 17, 2008

(54) EVAPORATION APPARATUS AND METHOD OF MAKING AN ORGANIC LAYER

(76) Inventors: Joo-hyeon LEE, Gyeonggi-do (KR); Chang-mo Park, Seoul (KR); Jin-koo Chung, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/938,093

(22) Filed: Nov. 9, 2007

(30) Foreign Application Priority Data
Jan. 11, 2007 (KR) 10-2007-0003507

(51) Int. Cl. C23C 14/54

(52) U.S. Cl. 427/9; 118/708

(57) ABSTRACT

An evaporation apparatus that is capable of determining the amount of organic material that is used for deposition of an organic layer (e.g. in an OLED) is presented. The apparatus evaporates an organic material through multiple stages and and includes: an evaporation source that evaporates the organic material and includes a heat source, a substrate supporter that supports a substrate, a sensor that senses a degree of evaporation of the organic material, a controller that calculates a deposition thickness of the organic material that is deposited during the stabilization stage, the deposition stage and the cooling stage by using the degree of evaporation sensed by the sensor, and a usage amount calculator that calculates a usage amount of the organic material by using a conversion factor between the deposition thickness of the organic material and the usage amount of the organic material, and the deposition thickness calculated by the controller.

### CROSS-REFERENCE TO RELATED APPLICATIONS

This application claims priority from Korean Patent Application No. 10-2007-0003507 filed on Jan. 11, 2007 in the Korean Intellectual Property Office, the disclosure of which is incorporated herein by reference.

### BACKGROUND OF THE INVENTION

1. Field of the Invention

The present invention relates to an evaporation apparatus and a method of making an organic layer.

2. Description of the Related Art

Flat panel display devices include liquid crystal display (LCD) devices and plasma display panels (PDPs). Recently, organic light emitting diode (OLED) devices have been gaining popularity for its desirable characteristics such as low driving voltage requirement, light weight, compactness, wide viewing angle, and fast response speed.

The OLED device operates as a light emitting layer and includes an organic material-that emits light. The OLED device is divided into a passive matrix type and an active matrix type according to the driving method.

OLED devices may be divided into a low molecular type and a polymer type depending on the molecular weight of an organic layer such as a hole injecting layer and a light emitting layer.

An organic layer such as the light emitting layer of the low molecular type may be formed by thermal evaporation. In this method, the organic material is vaporized and placed in contact with a substrate having a low temperature to form a solid organic layer upon phase transition.

This thermal evaporation method, however, is not without disadvantages. For example, the organic material is expensive and determines production costs of a display device depending on a managing method. Moreover, if the organic material is insufficient during the evaporation process, the process is suspended to supply the organic material, thereby making the process unstable.

Also, it is hard to determine the usage amount of the organic material in making the organic layer by using the thermal evaporation.

### SUMMARY OF THE INVENTION

Accordingly, it is an aspect of the present invention to provide an evaporation apparatus which determines the usage amount of an organic material.

Also, it is another aspect of the present invention to provide a method of making an organic layer which determines a usage amount of an organic material.

Additional aspects and/or advantages of the present invention will be set forth in part in the description which follows and, in part, will be obvious from the description, or may be learned by practice of the present invention.

The foregoing and/or other aspects of the present invention can be achieved by providing an evaporation apparatus that evaporates an organic material through a stabilization stage, a deposition stage and a cooling stage. The apparatus includes: an evaporation source that evaporates the organic material and includes a heat source, a substrate supporter that supports a substrate, a sensor that senses a degree of evaporation of the organic material, a controller that calculates a deposition thickness of the organic material that is deposited during the stabilization stage, the deposition stage and the cooling stage by using the degree of evaporation sensed by the sensor, and a usage amount calculator that calculates a usage amount of the organic material by using a conversion factor between the deposition thickness of the organic material and the usage amount of the organic material, and the deposition thickness calculated by the controller.

The sensor may sense the degree of evaporation of the organic material at the stabilization stage, the deposition stage and the cooling stage.

The sensor may sense a degree of evaporation of the organic material at the stabilization stage but be blocked from the organic vapor during the deposition stage and the cooling stage.

The controller may calculate the deposition thickness at the deposition stage by using a deposition thickness per time at the end of the stabilization stage and the time of performing the deposition stage, and calculate the deposition thickness at the cooling stage by using a prestored value.

The sensor may sense a degree of evaporation of the organic material at the stabilization stage and the deposition stage but is blocked from the organic vapor at the cooling stage.

The controller may calculate the deposition thickness at the cooling stage by using a prestored value.

The controller may control a temperature of the heat source based on the degree of evaporation of the organic material sensed by the sensor.

The foregoing and/or other aspects of the present invention can be achieved by providing a method of making an organic layer that evaporates an organic material through a stabilization stage, a deposition stage and a cooling stage. The method includes: calculating a conversion factor that converts a deposition thickness of the organic material into a usage amount of the organic material, sensing a degree of evaporation of the organic material, calculating a deposition thickness of the organic layer that is deposited during the stabilization stage, the deposition stage and the cooling stage by using the degree of evaporation of the organic material sensed by the sensor; and calculating a usage amount of the organic material by using the conversion factor and the calculated deposition thickness.

The degree of evaporation may be sensed at the stabilization stage, the deposition stage and the cooling stage.

According to an aspect of the invention, the degree of evaporation may be sensed at the stabilization stage, but not sensed at the deposition stage and the cooling stage.

The calculating of the deposition thickness at the deposition stage may include calculating the deposition thickness by using a deposition thickness per time at the end of the stabilization stage and the length of the deposition stage, and the calculating of the deposition thickness at the cooling stage may include calculating the deposition thickness by using a prestored value.

The sensing of the degree of evaporation may include sensing the degree of evaporation at the stabilization stage and the deposition stage but not at the cooling stage.

The calculating of the deposition thickness at the cooling stage may include calculating the deposition thickness by using a prestored value.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 is a circuit diagram of an organic light emitting diode (OLED) device which is manufactured according to the present invention;

FIG. 2 is a sectional view of the organic light emitting diode (OLED) device which is manufactured according to the present invention;

FIG. 3 is a block diagram of an evaporation apparatus according to an exemplary embodiment of the present invention;

FIGS. 4 and 5 illustrate the evaporation apparatus according to the exemplary embodiment of the present invention;

FIGS. 6A and 6B are graphs that illustrate a deposition speed of different organic layers according to time;

FIG. 7 illustrates a method of making an organic layer that uses the evaporation apparatus according to the exemplary embodiment of the present invention;

FIG. 8 is a flow chart which illustrates the method of forming the organic layer that uses the evaporation apparatus according to the exemplary embodiment of the present invention;

FIG. 9 illustrates another method of forming an organic layer that uses the evaporation apparatus according to the exemplary embodiment of the present invention; and

FIG. 10 illustrates another method of making an organic layer that uses the evaporation apparatus according to the exemplary embodiment of the present invention.

### DETAILED DESCRIPTION OF EMBODIMENTS

Hereinafter, embodiments of the present invention will be described with reference to accompanying drawings, wherein like numerals refer to like elements and repetitive descriptions will be avoided as necessary.

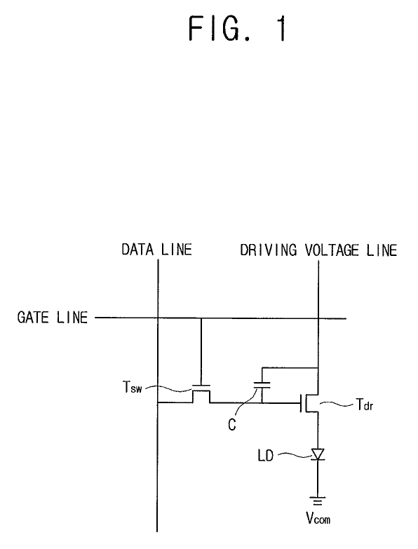

FIG. 1 is an equivalent circuit diagram of a pixel in a display device which is manufactured according to the present invention.

A pixel includes a plurality of signal lines. The signal lines include a gate line which supplies a scanning signal, a data line which supplies a data signal and a driving voltage line which supplies a driving voltage. The data line and the driving voltage line are adjacent to and usually parallel to each other. The gate line extends perpendicularly to the data line and the driving voltage line.

The pixels include an organic light emitting device LD, a switching thin film transistor Tsw, a driving thin film transistor Tdr and a capacitor C.

The driving thin film transistor Tdr includes a control terminal, an input terminal and an output terminal. The control terminal is connected with the switching thin film transistor Tsw. The input terminal is connected with the driving voltage line. The output terminal is connected with the organic light emitting device LD.

The organic light emitting device LD includes an anode that is connected with the output terminal of the driving thin film transistor Tdr and a cathode that is connected with a common voltage Vcom. The organic light emitting device LD emits lights in different intensities depending on the output current of the driving thin film transistor Tdr, thereby displaying an image. The current that is output by the driving thin film transistor Tdr depends on the voltage between the control terminal and the output terminal.

The switching thin film transistor Tsw includes a control terminal, an input terminal and an output terminal. The control terminal is connected with the gate line, and the input terminal is connected with the data line. The output terminal of the switching thin film transistor Tsw is connected with the control terminal of the driving thin film transistor Tdr. The switching thin film transistor Tsw transmits the data signal supplied to the data line to the driving thin film transistor Tdr according to the scanning signal supplied to the gate line.

The capacitor C is connected between the control terminal and the input terminal of the driving thin film transistor Tdr. The capacitor C charges and maintains the data signal inputted to the control terminal of the driving thin film transistor Tdr.

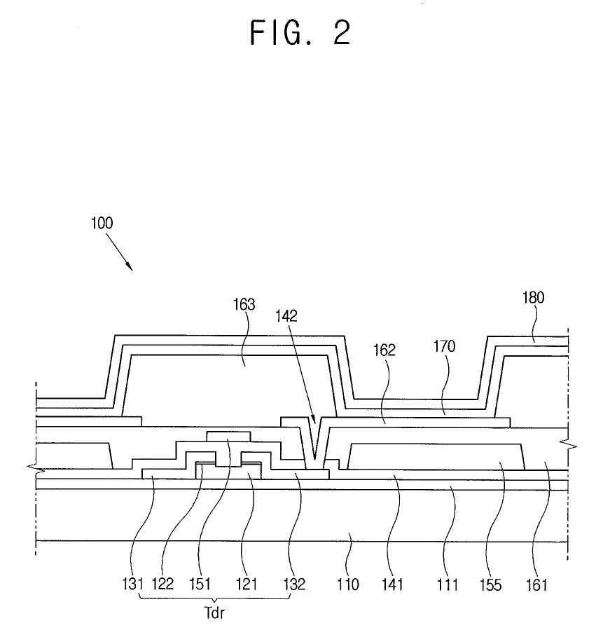

Hereinafter, a display device 100 which is manufactured according to the present invention will be described with reference to FIG. 2. FIG. 2 illustrates the driving thin film transistor Tdr.

A buffer layer 111 is formed on an insulating substrate 110 including an insulating material such as glass, quartz, ceramic or plastic. The buffer layer 111, which may include silicon oxide (SiOx), prevents impurities of the insulating substrate 110 from being introduced to a semiconductor layer 121 during the crystallization of the semiconductor layer 121.

The semiconductor layer 121 includes polysilicon and is formed on the buffer layer 111. An ohmic contact layer 122 is formed on the semiconductor layer 121 and is divided into two parts. The ohmic contact layer 122 includes n+ poly silicon highly doped with an n-type dopant.

A source electrode 131 and a drain electrode 132 are formed on the ohmic contact layers 122 that are divided into two parts. The source electrode 131 and the drain electrode 132 are simultaneously formed. The source electrode 131 and the drain electrode 132 may include a single metal layer or multiple metal layers.

A first insulating layer 141 is formed on the source electrode 131, the drain electrode 132 and the semiconductor layer 121. The first insulating layer 141 may include silicon nitride (SiNx).

A gate electrode 151 is formed on the first insulating layer 141 corresponding to a channel region. The gate electrode 151 may include a single metal layer or multiple metal layers.

A color filter 155 is formed on the first insulating layer 141.

An organic layer 170 of the display device 100 emits white light, which is emitted through the insulating substrate 110.

The white light emitted from the organic layer 170 is colored red, green and blue colors by traveling through the color filter 155.

A second insulating layer 161 is formed on the gate electrode 151, the first insulating layer 141, and the color filter 155. The second insulating layer 161 serves as a planarization layer and may include an organic material. The organic material may employ one of benzocyclobutene (BCB) series, olefin series, acrylic resin series, polyimide series, fluoropolymer, etc.

A pixel electrode 162 as a transparent electrode is formed on the second insulating layer 161. The pixel electrode 162 includes a transparent conductive material such as indium tin oxide (ITO), indium zinc oxide (IZO), etc.

A contact hole 142 is formed on the first and second insulating layers 141 and 161 and extends to the drain electrode 132. The pixel electrode 162 is electrically connected with the drain electrode 132 through the contact hole 142. The pixel electrode 162 is herein referred to as an anode and supplies holes to the organic layer 170.

A wall 163 is formed between neighboring pixel electrodes 162. The wall 163 defines a pixel region. The wall 163 includes a photoresist material such as acrylic resin, or polyimide resin which has heat resistance and solvent resistance, or an inorganic material such as SiO2 and TiO2. The wall 163 may have a double-layer structure with a first layer of organic material and a second layer of inorganic material.

The organic layer 170 is formed on the wall 163 and the pixel electrodes 162.

The organic layer 170 includes a light emitting layer emitting white light. The organic layer 170 may further include an electron injecting layer, an electron transport layer, a hole injecting layer and a hole transport layer.

The hole injecting layer and the hole transport layer may employ an amine derivative which is highly fluorescent, e.g., a triphenyl diamine derivative, a styryl amine derivative, and an amine derivative having an aromatic condensed ring.

The electron transport layer may employ a quinoline derivative, such as aluminum tris(8-hydroxyquinoline) (Alq3). The electron transport layer may also employ a phenyl anthracene derivative and a tetra arylethene derivative. The electron injecting layer may include barium or calcium.

The light emitting layer may include red, green and blue light emitting layers. The different colored lights are combined to produce the white light.

The organic layer 170 is formed on the wall 163 and the pixel electrodes 162. As shown in FIG. 2, some layer(s) that are covered by the organic layer 170 may be formed on the wall 163 and the pixel electrodes 162 while other layer(s) that are covered by the organic layer 170 are mainly formed on the pixel electrodes 162.

A common electrode 180 is disposed on the wall 163 and the organic layer 170. The common electrode 180 is herein referred to as a cathode and supplies electrons to the organic layer 170. The common electrode 180 may be formed by a calcium layer and an aluminum layer.

The common electrode 180 may have a reflective property. In this case, light from the organic layer 170 is emitted thorough the insulating substrate 110.

A hole transmitted from the pixel electrodes 162 and an electron transmitted from the common electrode 180 are combined into an exciton in the organic layer 170. Light is emitted as the exciton transitions energy levels.

The display device 100 may further include a passivation layer (not shown) to protect the common electrode 180, and an encapsulating member (not shown) to prevent moisture and air from being introduced to the organic layer 170. The encapsulating member may include a sealing resin and a sealing can.

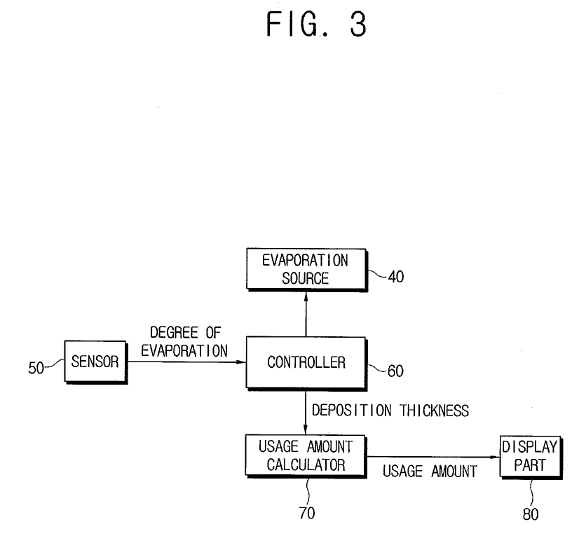

Hereinafter, an evaporation apparatus 1 according to an exemplary embodiment of the present invention will be described with reference to FIGS. 3 to 5.

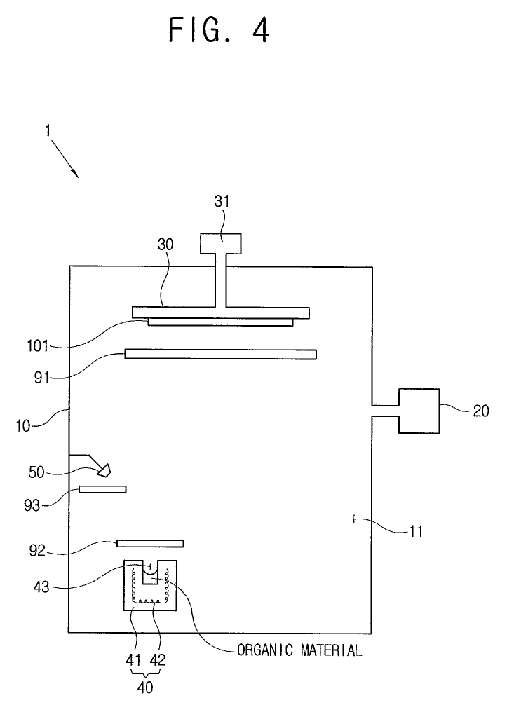

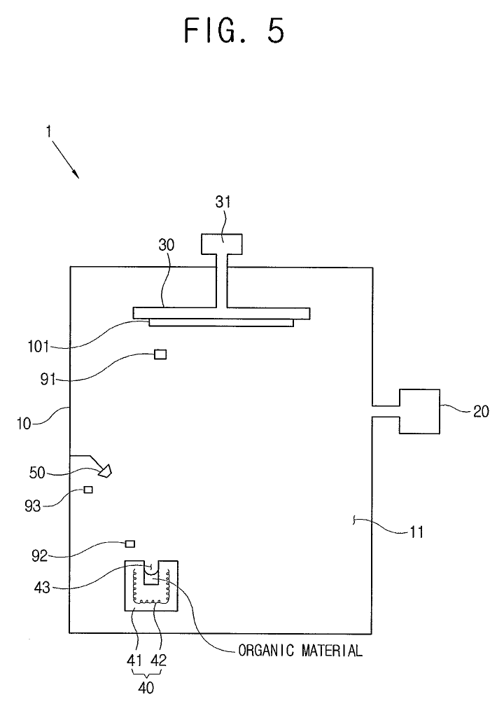

FIG. 3 is a block diagram of an evaporation apparatus 1 according to an exemplary embodiment of the present invention. FIG. 4 illustrates opening and closing parts 91, 92 and 93 which are all closed while FIG. 5 illustrates the opening and closing parts 91, 92 and 93 which are open. FIGS. 4 and 5 illustrate a substrate 101 which is mounted on a substrate supporter 30, and an organic material which is accommodated in an evaporation source 40.

The organic layer is to be formed on the substrate 101. In some embodiments, the pixel electrodes 162 and the wall 163 may be formed on the substrate 101 of the display device 100 in FIG. 2 prior to applying the evaporation apparatus 1. Similarly, if the organic layer includes several layers, a part of the organic layer may be already formed on the substrate 101 before the evaporation apparatus 1 is used.

The evaporation apparatus 1 includes a vacuum chamber 10 which forms an evaporation space 11, a vacuum pump 20 which adjusts the pressure in the vacuum chamber 10, the substrate supporter 30 which is formed on an upper part of the evaporation space 11 and supports the substrate 101, the evaporation source 40 which is formed on a lower part of the evaporation space 11, and a sensor 50 which is formed on the evaporation source 40 and senses the degree of evaporation.

The evaporation apparatus 1 further includes a controller 60 which calculates a deposition thickness by using a degree of evaporation sensed by the sensor 50 and controls the degree of evaporation of the evaporation source 40, a usage amount calculator 70 (see FIG. 3) which calculates the usage amount of the organic material by using the deposition thickness calculated by the controller 60 (see FIG. 3), a display part 80 which displays a calculation result of the usage amount calculator 70, and the opening and closing parts 91, 92 and 93.

The evaporation apparatus 1 further includes a pressure gauge (not shown) which detects the pressure in the evaporation space 11, and a mask supporter (not shown) which is disposed between the substrate supporter 30 and the first opening and closing part 91 and supports a mask. The mask may include an open mask or a shadow mask.

Hereinafter, “deposition thickness” refers to a value calculated by the controller 60 on the assumption that organic vapor generated by the evaporation source 40 is deposited on the substrate 101. The “deposition thickness” is calculated regardless of whether the organic material is actually deposited on the substrate 101.

A surface of the substrate supporter 30 supports the substrate 101 on its lower surface such that the substrate 101 is facing away from the walls of the evaporation space 11, i.e. toward the evaporation source 40. A rotation driver 31 is connected with the substrate supporter 30, and rotates the substrate supporter 30 while the organic material is deposited on the substrate 101, thereby forming the organic layer with uniform thickness.

The evaporation source 40 includes a main body 41 and a heat source 42 which is formed within the main body 41. An upper surface of the main body 41 is concave and forms an organic material accommodation space 43 to accommodate the organic material to be deposited therein. The heating of the heat source 42 is controlled by the controller 60.

When the heat source 42 is activated, the organic material placed in the organic material accommodation space 43 is heated and evaporated to generate the organic vapor.

The sensor 50 is positioned above the evaporation source 40 and senses the degree of evaporation of the organic material. The sensor 50 may include a crystal oscillator although this is not a limitation of the invention. The crystal oscillator may include quartz.

Where a crystal oscillator is used, the crystal oscillator initially generates a frequency of about 6 MHz. The frequency of the crystal oscillator decreases as more organic material is deposited thereon. The degree of evaporation of the organic material may be determined by the change in frequency. Here, the degree of evaporation is proportional to the evaporation amount of the organic material. The deposition speed is proportional to the degree of evaporation.

The controller 60 calculates the deposition thickness of the organic material based on the degree of evaporation of the organic material sensed by the sensor 50, i.e. the change in oscillation frequency. The process of calculating the deposition thickness of the organic material will be described in more detail below.

The controller 60 calculates the deposition speed, i.e. the deposition thickness per time, by using the degree of evaporation of the organic material sensed by the sensor 50 and prestored information on the organic material. The information on the organic material may include the density of the organic material.

The controller 60 calculates the deposition thickness of the organic material by using the calculated deposition speed and the measured deposition time.

The deposition speed may be calculated by using a prestored value other than by using the degree of evaporation of the organic material sensed by the sensor 50, which will be described in detail with a method of forming the organic layer.

The usage amount calculator 70 stores a conversion factor between the deposition thickness and the usage amount of the organic material. The conversion factor is the usage amount of the organic material/deposition thickness, e.g., has a unit of g/kÅ. The conversion factor is determined by experiments. The method of determining the conversion factor will be described later. The conversion factor may have a unit of the deposition thickness/usage amount of the organic material depending on the calculating method.

The usage amount calculator 70 calculates the usage amount of the organic material by using the conversion factor and the deposition thickness calculated by the controller 60.

The display part 80 (FIG. 3) displays the initial amount of the organic material, the usage amount of the organic material, the current remaining amount of the organic material, etc. If the current remaining amount of the organic material is below a certain level or if the current remaining amount is not sufficient to form an organic layer completely, the usage amount calculator 70 may display a warning message through the display part 80.

Hereinafter, the opening and closing parts 91, 92 and 93 will be described.

If the first opening and closing part 91 is open, the substrate 101 mounted on the substrate supporter 30 is exposed to the organic vapor existing in the evaporation space 11. If the first opening and closing part 91 is closed, the substrate 101 is blocked from the organic vapor in the evaporation space 11. That is, even if the organic vapor is supplied to the evaporation space 11, the organic layer is formed on the substrate 101 only when the first opening and closing part 91 is open.

If the second opening and closing part 92 is open, the organic vapor is supplied from the evaporation source 40 to the evaporation space 11. If the second opening and closing part 92 is closed, the organic vapor is not supplied from the evaporation source 40 to the evaporation space 11.

If the third opening and closing part 93 is open, the sensor 50 is exposed to the organic vapor in the evaporation space 11. If the third opening and closing part 93 is closed, the sensor 50 is blocked from the organic vapor in the evaporation space 11. That is, even if the organic vapor is supplied to the evaporation space 11, the sensor 50 may sense the degree of evaporation only when the third opening and closing part 93 is open.

The organic material is evaporated in various stages, which will be described hereinafter.

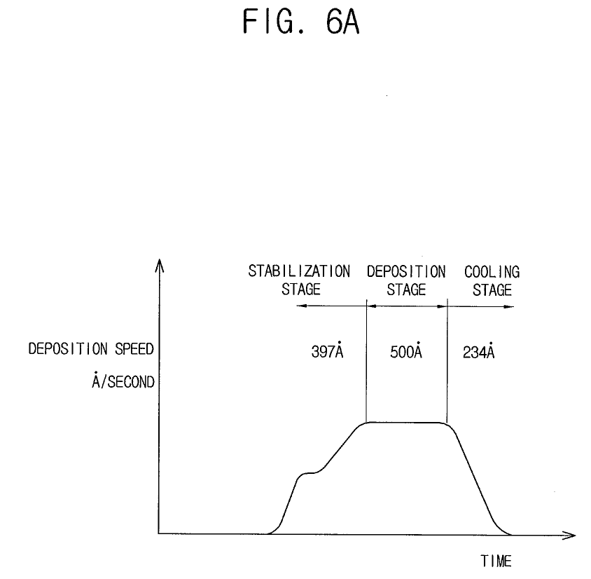

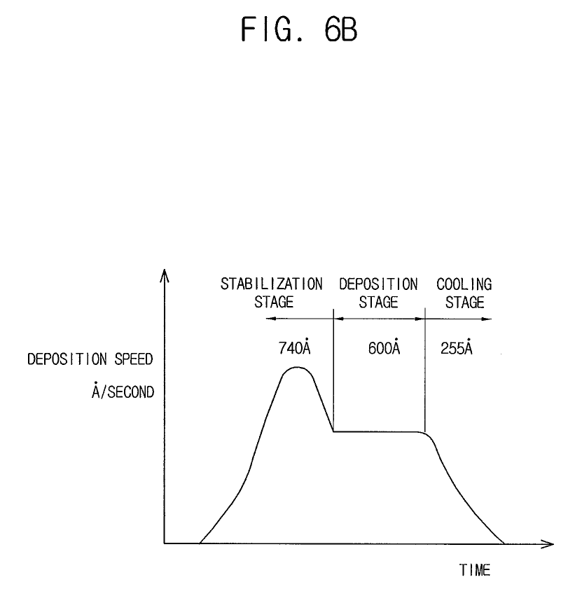

FIGS. 6A and 6B illustrate the deposition speed of different organic materials according to time, and illustrate a process of forming the organic layer once.

The organic material is evaporated through a stabilization stage, a deposition stage and a cooling stage.

The stabilization stage refers to a stage in which the organic vapor starts being generated and the deposition speed is stabilized at a desired value. As shown by the plot in FIGS. 6A and 6B, the deposition speed at the stabilization stage is not constant, and the deposition thickness at this stage varies depending on the organic material. Even if the same organic material is used, the deposition thickness at the stabilization stage may vary between batches.

A batch process forms a single organic layer and includes a stabilization stage, a deposition stage and a cooling stage. Typically, if the organic material is disposed in the evaporation source 40, a plurality of batches is performed without replenishing the organic material.

During the stabilization stage, the first opening and closing part 91 is closed and the organic vapor is not supplied to the substrate 101.

During the deposition stage, the organic vapor is supplied to the substrate 101 to form the organic layer. If the deposition speed is stabilized, the first opening and closing part 91 is open to supply the organic vapor to the substrate 101. Once the deposition speed is stabilized at the deposition stage, the deposition thickness is proportional to the deposition time. At this stage, a constant temperature of the evaporation source 40 is maintained.

If the deposition thickness reaches the desired value, power supplied to the heat source 41 is cut off and the organic material of the evaporation source 40 is cooled. At the cooling stage, the first opening and closing part 91 and/or the third opening and closing part 93 is closed not to supply the organic vapor to the substrate 101.

During the cooling stage, the deposition thickness varies depending on the organic material. However, the same organic material present a uniform deposition thickness without much batch-to-batch variation. This is possible since the same organic material is applied the same temperature during the deposition stage in each batch, i.e. the temperature remains constant in the beginning of the cooling stage, and has substantially uniform temperature variation profile at the cooling stage in each batch.

The organic vapor is generated at all stages of the stabilization stage, the deposition stage and the cooling stage. Meanwhile, the organic layer is formed on the substrate 101 by using the organic vapor at only the deposition stage. At the stabilization stage and the cooling stage, the deposition thickness has a significant value so that it may be thicker than that at the deposition stage depending on the type of the organic materials.

The conversion factor according to the present invention is determined in consideration of the deposition thickness at both the stabilization stage and the cooling stage, and thus fully reflects the actual usage amount of the organic material.

Hereinafter, a method of obtaining the conversion factor will be described.

The weight of the organic material placed in the evaporation source 40 is measured before being evaporated. Then, while forming the organic layer on the substrate 101, the deposition thickness at the stabilization stage, the deposition stage and the cooling stage is obtained. Then, the weight of the organic material is measured after being evaporated.

For example, if the changed weight of the organic material is 2.679 g and if the calculated deposition thickness is 2.320 kÅ, the conversion factor is 2.679 g/2.320 kÅ, i.e. 1.15 g/kÅ. The conversion factor is calculated for each organic material, and varies depending on the organic materials.

The conversion factor is calculated after several batches of organic layers are deposited, thereby enhancing the accuracy of the conversion factor. The organic layer may not be actually formed on the substrate 101 to calculate the conversion factor. The conversion factor may be estimated repeatedly as necessary, and may be reset.

When the conversion factor is calculated, the usage amount of the organic material may be estimated by using the conversion factor and the calculated deposition thickness of the organic layer as described above. For example, if the conversion factor is 1.15 g/kÅ and if the calculated deposition thickness of the organic layer is 2.120 kÅ, the usage amount of the organic material is 1.15 g/kÅ*2.120 kÅ, i.e. 2.438 g.

Hereinafter, various methods of making an organic layer and a method of calculating the deposition thickness by the controller 60 according thereto will be described.

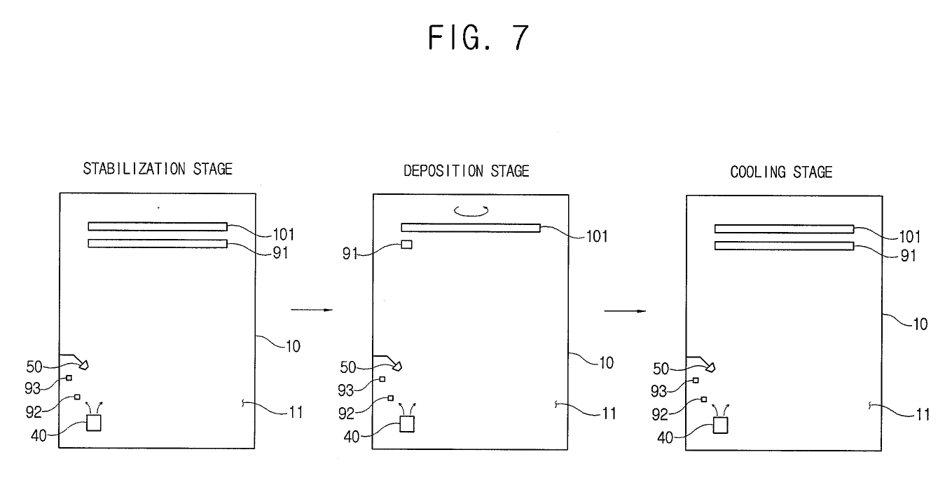

FIG. 7 illustrates a method of forming the organic layer.

At the stabilization stage, the first opening and closing part 91 is closed, and the second opening and closing part 92 and the third opening and closing part 93 are open.

During the stabilization stage, the organic vapor is supplied to the sensor 50. The sensor 50 senses the degree of evaporation. The controller 60 calculates the deposition thickness at the stabilization stage based on the degree of evaporation sensed by the sensor 50.

As the first opening and closing part 91 is closed, the organic vapor is not supplied to the substrate 101.

During the deposition stage, the first to third opening and closing parts 91, 92 and 93 are all open.

The organic vapor is supplied to the sensor 50. The sensor 50 senses the degree of evaporation. The controller 60 calculates the deposition thickness at the deposition stage based on the degree of evaporation sensed by the sensor 50.

As the first opening and closing part 91 is open, the organic vapor is supplied to the substrate 101 to make the organic layer.

During the cooling stage, the first opening and closing part 91 is closed, and the second and third opening and closing parts 92 and 93 are open. The organic vapor is supplied to the sensor 50, which senses the degree of evaporation. The controller 60 calculates the deposition thickness at the cooling stage based on the degree of evaporation sensed by the sensor 50.

As the first opening and closing part 91 is closed and the organic vapor is not supplied to the substrate 101.

As described above, the deposition thickness according to the present invention is calculated by the controller 60 by using the degree of evaporation sensed by the sensor 50.

The usage amount calculator 70 calculates the usage amount of the organic material by using the conversion factor and the deposition thickness calculated by the controller 60.

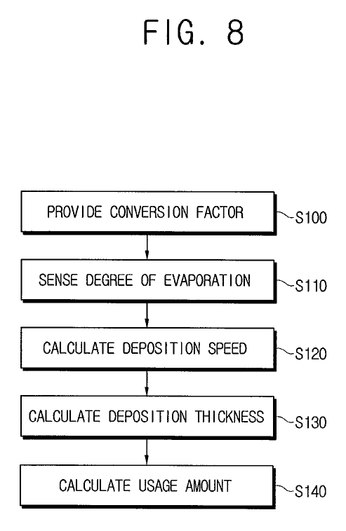

The method of calculating the deposition thickness and the usage amount of the organic material will be described again with reference to FIG. 8.

The conversion factor is calculated by using the deposition thickness and the actually measured usage amount of the organic material (S100). The conversion factor is stored in the usage amount calculator 70.

While the organic layer is formed on the substrate 101, the degree of evaporation that happens during the stabilization stage, the deposition stage and the cooling stage are determined (S110) The sensor 50 senses the degree of evaporation. The degree of evaporation may be determined by the change in frequency.

The controller 60 calculates the deposition speed based on the degree of evaporation sensed by the sensor 50 (S120). Here, the controller 60 may use the prestored information of the corresponding organic material to be evaporated, to calculate the deposition speed.

The controller 60 calculates the deposition thickness by using the calculated deposition speed and the time of performing the deposition stage (S130).

The usage amount calculator 70 calculates the usage amount of the organic material by multiplying the conversion factor by the deposition thickness calculated by the controller 60 (S140).

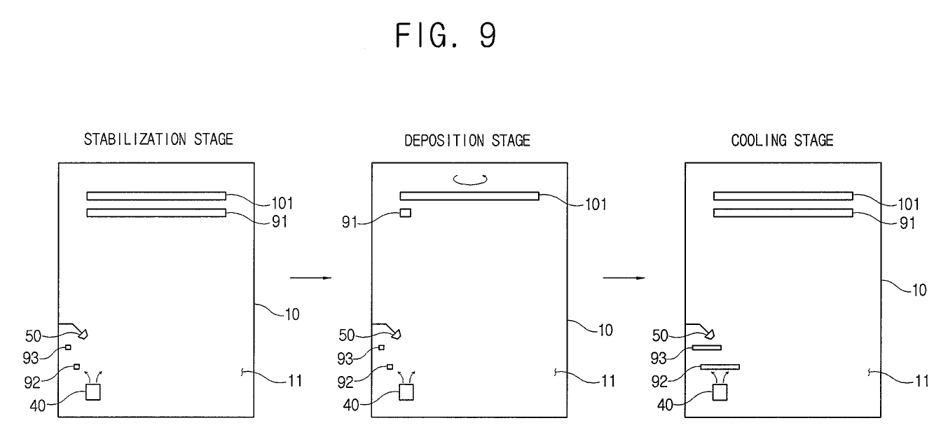

FIG. 9 illustrates another method of making the organic layer.

During the stabilization stage, the first opening and closing part 91 is closed, and the second and third opening and closing parts 92 and 93 are open. The organic vapor is supplied to the sensor 50, and the sensor 50 senses the degree of evaporation. The controller 60 calculates the deposition thickness during the stabilization stage based on the degree of evaporation sensed by the sensor 50. As the first opening and closing part 91 is closed, the organic vapor is not supplied to the substrate 101.

During the deposition stage, the first to third opening and closing parts 91, 92 and 93 are all open. The organic vapor is supplied to the sensor 50, and the sensor 50 senses the degree of evaporation. The controller 60 calculates the deposition thickness at the deposition stage based on the degree of evaporation sensed by the sensor 50. As the first opening and closing part 91 is open, the organic vapor is supplied to the substrate 101 to deposit the organic material.

During the cooling stage, the first to third opening and closing parts 91, 92 and 93 are all closed. The organic vapor is blocked from being supplied to the sensor 50, and is not supplied to the substrate 101.

As described above, the same organic material has substantially uniform deposition thickness at the cooling stage. The controller 60 stores the deposition thickness at the cooling stage therein. The stored value serves as the deposition thickness at the cooling stage.

The usage amount calculator 70 calculates the usage amount of the organic material by using the conversion factor and the deposition thickness calculated by the controller 60.

During the cooling stage, one of the second and third opening and closing parts 92 and 93 may be open. In this case, the controller 60 calculates the deposition thickness with the same method as described above.

According to the method illustrated in FIG. 9, the organic vapor is not supplied to the sensor 50 during the cooling stage. This way, the lifespan of the sensor 50 is increased.

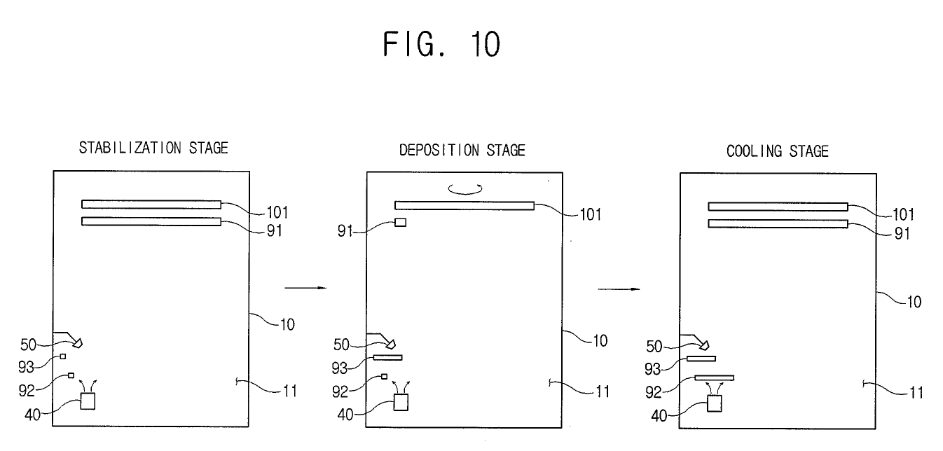

FIG. 10 illustrates another method of making the organic layer.

During the stabilization stage, the first opening and closing part 91 is closed and the second and third opening and closing parts 92 and 93 are open. The organic vapor is supplied to the sensor 50, and the sensor 50 senses the degree of evaporation. The controller 60 calculates the deposition thickness at the stabilization stage, based on the degree of evaporation sensed by the sensor 50. As the first opening and closing part 91 is closed, the organic vapor is not supplied to the substrate 101.

During the deposition stage, the first and second opening and closing parts 91 and 92 are open and the third opening and closing part 93 is closed. The organic vapor is supplied to the sensor 50 to deposit the organic material as the first opening and closing part 91 is open. As the third opening and closing part 93 is closed, the organic vapor is not supplied to the sensor 50.

As described above, the deposition speed is constant during the deposition stage. The deposition thickness may be calculated if the time of performing the deposition stage is measured. Thus, the controller 60 calculates the deposition thickness at the deposition stage based on the deposition speed at the end of the stabilization stage and the time of performing the deposition stage.

During the cooling stage, the first to third opening and closing parts 91, 92 and 93 are closed. The organic vapor is blocked from being supplied to the sensor 50, and is not supplied to the substrate 101.

As described above, the same organic material has a substantially uniform deposition thickness during the cooling stage. The controller 60 stores the thickness of the deposition that happens during the cooling stage. The stored value serves as the deposition thickness at the cooling stage.

The usage amount calculator 70 calculates the usage amount of the organic material by using the conversion factor and the deposition thickness calculated by the controller 60.

During the cooling stage of the method illustrated in FIG. 10, one of the second and third opening and closing parts 92 and 93 may be open. In this case, the controller 60 calculates the deposition thickness with the same method as described above.

According to the present invention, the organic vapor is not supplied to the sensor 50 at the deposition stage and the cooling stage, thereby increasing lifetime of the sensor 50.

The method of calculating the deposition thickness by the controller 60, i.e. the method of using the prestored deposition thickness at the deposition stage and/or the cooling stage may be applicable to calculating the conversion factor.

According to the present invention, the conversion factor and the deposition thickness are calculated while taking into consideration the entire process of evaporating the organic material. Thus, the usage amount of the organic material is relatively precisely estimated.

The second half of the cooling stage, which accounts for a small portion in usage amount of the organic material, may be excluded from the process of calculating the conversion factor and/or the deposition thickness.

As described above, the present invention provides an evaporation apparatus which determines the usage amount of an organic material, and a method of forming an organic layer.

Although exemplary embodiments of the present invention have been shown and described, it will be appreciated by those skilled in the art that changes may be made in these exemplary embodiments without departing from the principles and spirit of the invention, the scope of which is defined in the appended claims and their equivalents.

What is claimed is:

1. An evaporation apparatus that evaporates an organic material through a stabilization stage, a deposition stage and a cooling stage, the apparatus comprising:
an evaporation source that evaporates the organic material and includes a heat source;
a substrate supporter that supports a substrate;
a sensor which senses a degree of evaporation of the organic material;
a controller that calculates a deposition thickness of the organic material that is deposited during the stabilization stage, the deposition stage and the cooling stage by using the degree of evaporation sensed by the sensor; and
a usage amount calculator that calculates a usage amount of the organic material by using a conversion factor between the deposition thickness of the organic material and the usage amount of the organic material, and the deposition thickness calculated by the controller.

2. The evaporation apparatus according to claim 1, wherein the sensor senses the degree of evaporation of the organic material during the stabilization stage, the deposition stage and the cooling stage.

3. The evaporation apparatus according to claim 1, wherein the sensor senses a degree of evaporation of the organic material at the stabilization stage but is blocked from the organic vapor at the deposition stage and the cooling stage.

4. The evaporation apparatus according to claim 3, wherein the controller calculates the deposition thickness at the deposition stage by using a deposition thickness per time at the end of the stabilization stage and the time of performing the deposition stage, and calculates the deposition thickness at the cooling stage by using a prestored value.

5. The evaporation apparatus according to claim 1, wherein the sensor senses a degree of evaporation of the organic material at the stabilization stage and the deposition stage but is blocked from the organic vapor at the cooling stage.

6. The evaporation apparatus according to claim 5, wherein the controller calculates the deposition thickness at the cooling stage by using a prestored value.

7. The evaporation apparatus according to claim 1, wherein the controller controls a temperature of the heat source based on the degree of evaporation of the organic material sensed by the sensor.

8. A method of making an organic layer by evaporating an organic material through a stabilization stage, a deposition stage and a cooling stage, the method comprising:
calculating a conversion factor that converts a deposition thickness of the organic material into a usage amount of the organic material;
sensing a degree of evaporation of the organic material;
calculating a deposition thickness of the organic layer that is deposited during the stabilization stage, the deposition stage and the cooling stage by using the degree of evaporation of the organic material sensed by the sensor; and
calculating a usage amount of the organic material by using the conversion factor and the calculated deposition thickness.

9. The method according to claim 8, wherein the degree of evaporation is sensed during the stabilization stage, the deposition stage and the cooling stage.

10. The method according to claim 8, wherein the degree of evaporation is sensed at the stabilization stage but not sensed at the deposition stage and the cooling stage.

11. The method according to claim 10, wherein the calculating of the deposition thickness at the deposition stage comprises calculating the deposition thickness by using a deposition thickness per time at the end of the stabilization stage and the length of the deposition stage, and the calculating of the deposition thickness at the cooling stage comprises calculating the deposition thickness by using a prestored value.

12. The method according to claim 8, wherein the sensing of the degree of evaporation comprises sensing the degree of evaporation at the stabilization stage and the deposition stage but not at the cooling stage.

13. The method according to claim 12, wherein the calculating of the deposition thickness at the cooling stage comprises calculating the deposition thickness by using a prestored value.
